(19) United States
(12) Patent Application Publication
(10) Pub. No.: US 2013/0240885 A1
(43) Pub. Date: Sep. 19, 2013

(54) SEMICONDUCTOR SUBSTRATE, AND SEMICONDUCTOR CHIP AND STACKED SEMICONDUCTOR PACKAGE HAVING THE SAME

(71) Applicants: Hyun Joo KIM, Icheon-si (KR); Kang Won LEE, Icheon-si (KR); Gyu Jei LEE, Seoul (KR)

(72) Inventors: Hyun Joo KIM, Icheon-si (KR); Kang Won LEE, Icheon-si (KR); Gyu Jei LEE, Seoul (KR)

(73) Assignee: SK HYNIX INC., Icheon-si (KR)

(21) Appl. No.: 13/565,134

(22) Filed: Aug. 2, 2012

(30) Foreign Application Priority Data
Mar. 15, 2012 (KR) 10-2012-26495

(51) Int. Cl. H01L 29/16

(52) U.S. Cl. 257/49; 257/E29.082

(57) ABSTRACT

A semiconductor chip includes a semiconductor substrate including a substrate body divided into device regions and a peripheral region generally outside the device regions, and having one surface generally facing away from an other surface, and trenches which are defined generally in the device regions substantially on the one surface; and an active layer formed substantially in the trenches and made of polysilicon; semiconductor devices formed substantially over the active layer; and through electrodes substantially passing through the peripheral region of the substrate body.

### CROSS-REFERENCE TO RELATED APPLICATIONS

The present application claims priority to Korean patent application number 10-2012-26495 filed on Mar. 15, 2012, which is incorporated herein by reference in its entirety.

### BACKGROUND OF THE INVENTION

1. Technical Field

The present invention relates to a semiconductor substrate suitable for improving a gettering characteristic, and a semiconductor chip and a stacked semiconductor package having the same.

In the semiconductor industry, packaging technologies for is integrated circuits have continuously been developed to satisfy the demand toward miniaturization and mounting reliability. Recently, as miniaturization and high performance are demanded in electric and electronic appliances, various stacking techniques have been developed.

2. Related Art

The term “stack” that is referred to in the semiconductor industry means to vertically pile at least two semiconductor chips or semiconductor packages. In the case of a memory device, by using a stacking technology, it is possible to realize a product having memory capacity at least two times greater than that obtainable through semiconductor integration processes. Since stacked semiconductor packages have advantages in terms of not only memory capacity but also mounting density and mounting area utilization efficiency, research and development for stacked semiconductor packages have been accelerated.

As an example of a stacked semiconductor package, a structure has been proposed, in which through electrodes are formed in semiconductor chips so that upper and lower semiconductor chips are physically and electrically connected with one another by the through electrodes.

However, a substance used as the through electrodes, for example, copper, is likely to diffuse to a semiconductor chip to cause a crystal defect. As a consequence, leakage current may be induced in the semiconductor chip, and the threshold voltage of a transistor is likely to be shifted, by which a refresh characteristic may deteriorate.

In order to cope with this problem, a method has been disclosed, in which the thickness of a dielectric layer (SiO₂) formed between a through electrode and a semiconductor chip is increased so that copper diffusing toward the semiconductor chip can be gettered by the dielectric layer. Nevertheless, the dielectric layer is not sufficient to getter the copper diffusing from the through electrode.

### BRIEF SUMMARY OF THE INVENTION

An embodiment of the present invention is directed to a semiconductor substrate suitable for improving a gettering characteristic.

Also, an embodiment of the present invention may be directed to a semiconductor chip having the semiconductor substrate.

Further, an embodiment of the present invention may be directed to a stacked semiconductor package having the semiconductor chip.

In one embodiment of the present invention, semiconductor substrate comprises: a substrate body divided into device regions and a peripheral region generally outside the device regions, and having one surface generally facing away from an other surface, and trenches which are defined generally in the device regions substantially on the one surface; and an active layer formed substantially in the trenches and made of polysilicon.

In another embodiment of the present invention, a semiconductor chip comprises: a substrate body divided into device regions and a peripheral region generally outside the device regions, and having one surface generally facing away from an other surface, and trenches which are defined generally in the device regions substantially on the one surface, an active layer formed substantially in the trenches and made of polysilicon; semiconductor devices formed substantially over the active layer; and through electrodes substantially passing through the peripheral region of the substrate body.

The semiconductor devices comprise, at least, any one of an image sensor, a memory semiconductor, a system semiconductor, a passive device, an active device, or a sensor semiconductor.

The semiconductor chip further comprises a circuit pattern formed substantially on the one surface of the substrate body and the active layer, wherein the circuit pattern comprises: bonding pads formed substantially over a second surface of the circuit pattern generally facing away from a first surface of the circuit pattern which generally faces the one surface of the substrate body and the active layer, and the bonding pads being electrically connected with the through electrodes; wiring layers electrically connecting the semiconductor devices to the through electrodes; and a dielectric layer substantially isolating the semiconductor devices from the wiring layers, the wiring layers from one another, and the wiring layers from the bonding pads.

The through electrodes may substantially pass through the circuit pattern and are directly connected to the bonding pads.

Unlike this, the through electrodes may only pass through the peripheral region of the substrate body, the one surface, and the other surface. In this case, the circuit pattern further comprises additional wiring layers which electrically connect the through electrodes with the bonding pads.

In another embodiment of the present invention, a stacked semiconductor package comprises: a plurality of semiconductor chips each including a semiconductor substrate including a substrate body divided into device regions and a peripheral region generally outside the device regions, and having one surface generally facing away from an other surface, and trenches which are defined generally in the device regions substantially on the one surface, and an active layer formed substantially in the trenches and made of polysilicon; semiconductor devices formed substantially over the active layer; and through electrodes passing through the peripheral region of the substrate body, the plurality of semiconductor chips being stacked such that their through electrodes are electrically connected with one another; and conductive connection members electrically connecting the through electrodes of the stacked semiconductor chips.

The semiconductor devices of each semiconductor chip comprise, at least, any one of an image sensor, a memory semiconductor, a system semiconductor, a passive device, an active device, or a sensor semiconductor.

Each semiconductor chip further includes a circuit pattern formed substantially on the one surface of the substrate body and the active layer, and wherein the circuit pattern comprises: bonding pads formed substantially over a second surface of the circuit pattern generally facing away from a first surface of the circuit pattern which generally faces the one surface of the substrate body and the active layer, and the bonding pads being electrically connected with the through electrodes; wiring layers electrically connecting the semiconductor devices to the through electrodes; and a dielectric layer substantially isolating the semiconductor devices from the wiring layers, the wiring layers from one another, and the wiring layers from the bonding pads.

The through electrodes may substantially pass through the circuit pattern and are directly connected to the bonding pads.

Unlike this, the through electrodes may only pass through the peripheral region of the substrate body, the one surface, and the other surface. In this case, the circuit pattern further comprises additional wiring layers which electrically connect the through electrodes with the bonding pads.

The stacked semiconductor package further includes a first dielectric layer formed, substantially under a lower surface of a lowermost semiconductor chip among the stacked semiconductor chips in, and formed to substantially expose the through electrodes of the lowermost semiconductor chip; redistribution lines formed substantially under the first dielectric layer and electrically connected with the through electrodes substantially exposed through the first dielectric layer; and a second dielectric layer formed, substantially under the first dielectric layer including the redistribution lines, and formed to expose portions of the redistribution lines.

Unlike this, the stacked semiconductor package further comprises a structural body supporting the semiconductor chips and having connection electrodes which are electrically is connected with the through electrodes of the lowermost semiconductor chip among the stacked semiconductor chips. The structural body comprises any one of a printed circuit board, an interposer, or a semiconductor package.

### BRIEF DESCRIPTION OF THE DRAWINGS

FIG. 1 is a cross-sectional view illustrating an example of a semiconductor chip in accordance with a first embodiment of the present invention.

FIG. 2 is a cross-sectional view illustrating an example of the semiconductor substrate illustrated in FIG. 1.

FIG. 3 is a cross-sectional view illustrating an example of a stacked semiconductor package in accordance with a second embodiment of the present invention.

FIG. 4 is a cross-sectional view illustrating an example of a stacked semiconductor package in accordance with a third embodiment of the present invention.

FIG. 5 is a cross-sectional view illustrating an example of a stacked semiconductor package in accordance with a fourth embodiment of the present invention.

FIG. 6 is a perspective view illustrating an example of an electronic apparatus having the semiconductor chip according to the present invention.

FIG. 7 is a block diagram showing an example of the electronic apparatus having the semiconductor chip according to the present invention.

### DETAILED DESCRIPTION

Hereafter, specific embodiments of the present invention will be described with reference to the accompanying drawings.

The figures are provided to allow those having ordinary skill in the art to understand the scope of the embodiments of the disclosure. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It is to be understood herein that the drawings are not necessarily to scale and in some instances proportions may have been exaggerated in order to more clearly depict certain features of the invention. In this specification, specific terms have been used. The terms are used to describe the present invention, and are not used to qualify the sense or limit the scope of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

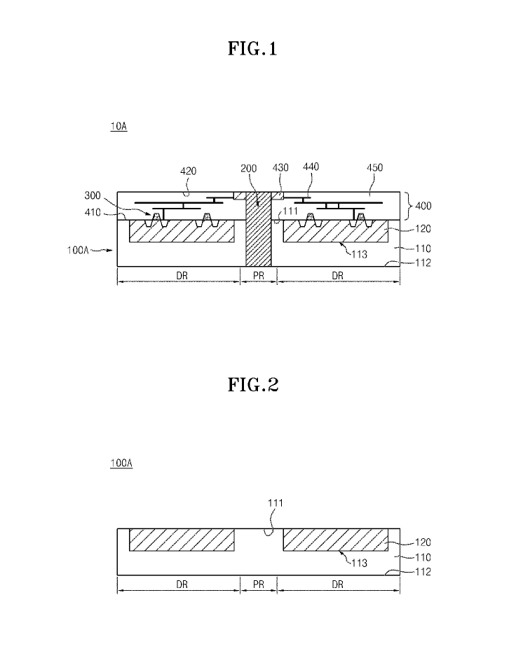

FIG. 1 is a cross-sectional view illustrating an example of a semiconductor chip in accordance with a first embodiment of the present invention, and FIG. 2 is a cross-sectional view illustrating an example of the semiconductor substrate illustrated in FIG. 1.

Referring to FIG. 1, a semiconductor chip 10A in accordance with a first embodiment of the present invention may include a semiconductor substrate 100A, through electrodes 200, and semiconductor devices 300. Besides, the semiconductor chip 10A may further include a circuit pattern 400.

Referring to FIG. 2, the semiconductor substrate 100A may include a substrate body 110 and an active layer 120.

The substrate body 110 may be divided into device regions DR and a peripheral region PR. The substrate body 110 may have one surface 111, the other surface 112 which may generally face away from the one surface 111, and trenches 113 which may be defined in the device regions DR generally on the one surface 111.

The active layer 120 may be formed substantially in the is trenches 113 and may be made of polysilicon.

The semiconductor substrate 110A may be a semiconductor substrate which may be manufactured on a wafer or may be a semiconductor substrate which may be manufactured on a wafer and may then individualized.

Referring back to FIG. 1, the through electrodes 200 may pass through the peripheral region PR of the substrate body 110. A substance used as the through electrodes 200 may include, at least, any one selected from the group consisting of copper, aluminum, an aluminum alloy, SnAg and Au.

While not illustrated, a dielectric layer may be formed substantially between the through electrodes 200 and the substrate body 110. The dielectric layer may include, at least, any one selected from the group consisting of an oxide layer, a nitride layer and an organic layer.

The semiconductor devices 300 may be formed substantially on the active layer 120. The semiconductor devices 300 may include, for example, at least one selected from the group consisting of an image sensor, a memory semiconductor, a system semiconductor, a passive device, an active device, and a sensor semiconductor.

The circuit pattern 400 may be formed substantially on the one surface 111 of the substrate body 110 and the active layer 120. The circuit pattern 400 may include a first surface 410, a second surface 420, bonding pads 430, wiring layers 440, and a dielectric layer 450.

The first surface 410 may generally face the one surface 111 of the substrate body 110 and the active layer 120, and the second surface 420 may face away from the first surface 410. The bonding pads 430 may be formed substantially on the second surface 420 and may be electrically connected with the through electrodes 200. The wiring layers 440 may electrically connect the semiconductor devices 300 and the bonding pads 430 with each other. The dielectric layer 450 may electrically isolate the semiconductor devices 300 and the wiring layers 440 from each other, the wiring layers 440 from one another, and the wiring layers 440 and the bonding pads 430 from each other.

In the present embodiment, the through electrodes 200 may pass through the circuit pattern 400 and may be directly connected with the bonding pads 430. Unlike this, while not illustrated in a drawing, the through electrodes 200 may not pass through the circuit pattern 400, and in this case, the circuit pattern 400 may further include additional wiring layers (not illustrated) which electrically connect the through electrodes 200 with the bonding pads 430.

Hereinbelow, stacked semiconductor packages having the above-described semiconductor chip will be described.

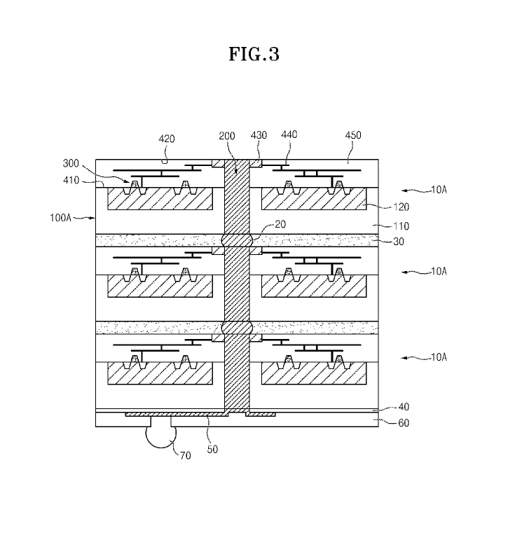

FIG. 3 may be a cross-sectional view illustrating an is example of a stacked semiconductor package in accordance with a second embodiment of the present invention.

Referring to FIG. 3, after preparing a plurality of semiconductor chips 10A each having an active layer 120 made of polysilicon, through electrodes 200 and semiconductor devices 300, the plurality of semiconductor chips 10A may be substantially vertically stacked such that their through electrodes 200 may be electrically connected with one another.

Conductive connection members 20 may be formed generally between the through electrodes 200 of the stacked semiconductor chips 10A to electrically connect the through electrodes 200 of upper and lower semiconductor chips 10A, and adhesive members 30 may be formed substantially between the stacked semiconductor chips 10A to attach upper and lower semiconductor chips 10A to each other.

The conductive connection members 20 may be formed of a metal including at least one of copper, tin, or silver, and the adhesive members 30 may include at least one of a non-conductive film (NCF), a non-conductive paste (NCP), an anisotropic conductive film (ACF), an anisotropic conductive paste (ACP), or a polymer.

A first dielectric layer 40 may be formed substantially on the lower surface of a lowermost semiconductor chip 10A among the generally stacked semiconductor chips 10A in such a way as to substantially expose the through electrodes 200 of the lowermost is semiconductor chip 10A, and redistribution lines 50 may formed generally on the first dielectric layer 40 to be electrically connected with the through electrodes 200 of the lowermost semiconductor chip 10A. A second dielectric layer 60 may be formed generally on the first dielectric layer 40 including the redistribution lines 50 in such a way as to substantially expose portions of the redistribution lines 50, and external connection terminals 70 may be mounted to the portions of the redistribution lines 50 which may be substantially exposed through the second dielectric layer 60.

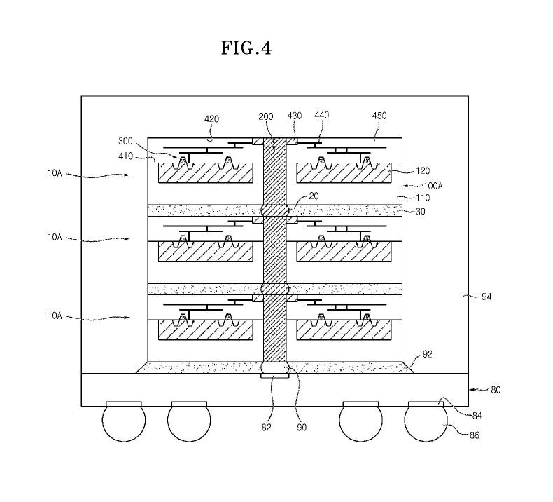

FIG. 4 is a cross-sectional view illustrating an example of a stacked semiconductor package in accordance with a third embodiment of the present invention.

Referring to FIG. 4, after preparing a plurality of semiconductor chips 10A each having an active layer 120 formed of polysilicon, through electrodes 200 and semiconductor devices 300, the plurality of semiconductor chips 10A may be generally vertically stacked such that their through electrodes 200 may be electrically connected with one another.

Conductive connection members 20 may be formed substantially between the through electrodes 200 of the stacked semiconductor chips 10A to electrically connect the through electrodes 200 of upper and lower semiconductor chips 10A, and adhesive members 30 may be formed substantially between the stacked semiconductor chips 10A to attach upper and lower is semiconductor chips 10A to each other.

The conductive connection members 20 may be formed of a metal including, at least, one of copper, tin, or silver, and the adhesive members 30 may include, at least, any one of a non-conductive film (NCF), a non-conductive paste (NCP), an anisotropic conductive film (ACF), an anisotropic conductive paste (ACP), or a polymer.

The semiconductor chips 10A may be mounted to a structural body 80 such that the through electrodes 200 of a lowermost semiconductor chip 10A among the stacked semiconductor chips 10A may be electrically connected with connection electrodes 82 of the structural body 80. In the present embodiment, the structural body 80 may include a printed circuit board (PCB).

The through electrodes 200 of the lowermost semiconductor chip 10A and the connection electrodes 82 of the structural body 80 may be electrically connected with each other by conductive connection members 90, and an adhesive member 92 may be formed substantially between the lowermost semiconductor chip 10A and the structural body 80 to attach the lowermost semiconductor chip 10A and the structural body 80 to each other. The conductive connection members 90 may be formed of a metal including, at least, one of copper, tin, or silver, and the adhesive member 92 may include, at least, any one of a non-conductive film (NCF), a is non-conductive paste (NCP), an anisotropic conductive film (ACF), an anisotropic conductive paste (ACP), or a polymer.

The upper surface of the structural body 80 including the stacked semiconductor chips 10A may be molded by a molding member 94. The reference numeral 84 designates ball lands, and the reference numeral 86 designates solder balls and may be used as external connection terminals.

While it was described in the sixth embodiment illustrated in FIG. 4 that the structural body 80 may include a printed circuit board, it may be noted that the structural body 80 may include a semiconductor package or an interposer.

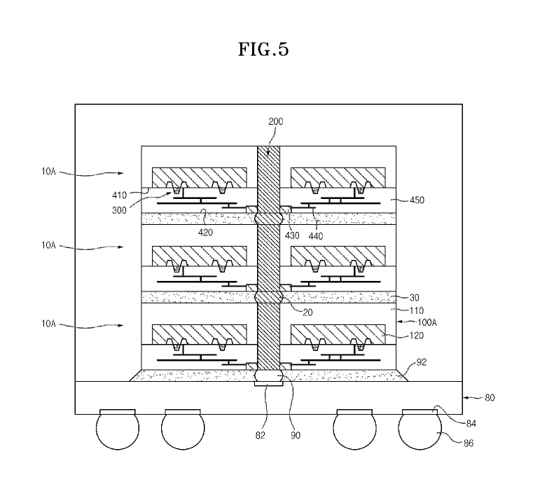

FIG. 5 is a cross-sectional view illustrating an example of a stacked semiconductor package in accordance with a fourth embodiment of the present invention.

Referring to FIG. 5, unlike the stacked semiconductor package in accordance with the third embodiment of the present invention described above with reference to FIG. 4, the stacked semiconductor package in accordance with the fourth embodiment of the present invention may have a construction where semiconductor chips 10A may be generally stacked in a face-down type generally on a structural body 80. Accordingly, the stacked semiconductor package in accordance with the fourth embodiment of the present invention may have the substantially the same or the same construction as the stacked semiconductor package in is accordance with the third embodiment of the present invention, except the stack type of the semiconductor chips 10A. Therefore, repeated descriptions for the same component elements will be omitted herein.

The aforementioned semiconductor chips may be applied to various electronic apparatuses.

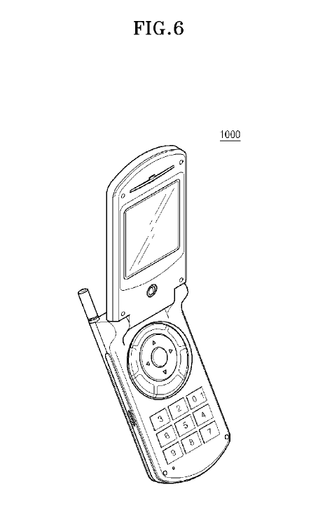

FIG. 6 is a perspective view illustrating an example of an electronic apparatus having the semiconductor chip according to the present invention.

Referring to FIG. 6, the semiconductor chip according to the embodiments of the present invention may be applied to an electronic apparatus 1000 such as a portable phone etc. Since the semiconductor chip according to the embodiments of the present invention has an excellent gettering characteristic, advantages may be provided for improving the performance and reliability of the electronic apparatus 1000. The electronic apparatus 1000 is not limited to the portable phone illustrated in FIG. 6, and may include various electronic appliances, for example, such as a mobile electronic appliance, a laptop computer, a notebook computer, a portable multimedia player (PMP), an MP3 player, a camcorder, a web tablet, a wireless phone, a navigator, a personal digital assistant (PDA), and so forth.

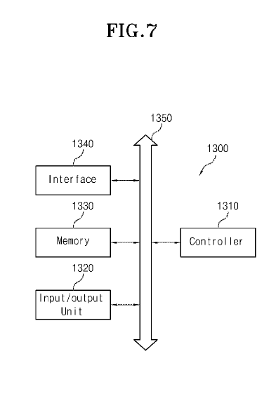

FIG. 7 is a block diagram showing an example of the electronic apparatus having the semiconductor chip according to the present invention.

Referring to FIG. 7, an electronic system 1300 may include a controller 1310, an input/output unit 1320, and a memory 1330. The controller 1310, the input/output unit 1320, and the memory 1330 may be coupled with one another through a bus 1350. The bus 1350 may serve as a path through which data may move. For example, the controller 1310 may include at least any one of at least one microprocessor, at least one digital signal processor, at least one microcontroller, or logic devices capable of performing the same functions as these components. The controller 1310 and the memory 1330 may include the semiconductor chip according to the present invention. The input/output unit 1320 may include at least one selected among a keypad, a keyboard, a display device, and so forth. The memory 1330 may be a device for storing data. The memory 1330 may store data and/or commands to be executed by the controller 1310, and the likes. The memory 1330 may include a volatile memory device and/or a nonvolatile memory device. Otherwise, the memory 1330 may be constituted by a flash memory. For example, a flash memory to which the technology of the present invention is applied may be mounted to an information processing system such as a mobile terminal or a desk top computer. The flash memory may be constituted by a solid state drive (SSD). In this case, the electronic system 1300 may stably store a large amount of data in a flash memory system. The is electronic system 1300 may further include an interface 1340 configured to transmit and receive data to and from a communication network. The interface 1340 may be a wired or wireless type. For example, the interface 1340 may include an antenna or a wired or wireless transceiver. Further, while not illustrated, a person skilled in the art will readily appreciate that the electronic system 1300 may be additionally provided with an application chipset, a camera image processor (CIS), an input/output unit, etc.

As is apparent from the above descriptions, according to the embodiments of the present invention, since a metal diffusing from through electrodes toward device regions may be effectively gettered at edge portions of polysilicon formed in the device regions, a gettering characteristic may be improved. As a consequence, it is possible to prevent leakage current from being induced in a semiconductor device and a threshold voltage of the semiconductor device from being shifted, whereby a refresh characteristic may be improved and the reliability and performance of a product may be ensured.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor substrate comprising:
a substrate body divided into device regions and a peripheral region generally outside the device regions, and having one surface generally facing away from an other surface, and trenches which are defined generally in the device regions substantially on the one surface; and
an active layer formed substantially in the trenches and made of polysilicon.

2. A semiconductor chip comprising:
a substrate body divided into device regions and a peripheral region generally outside the device regions, and having one surface generally facing away from an other surface, and trenches which are defined generally in the device regions substantially on the one surface, an active layer formed substantially in the trenches and made of polysilicon;
semiconductor devices formed substantially over the active layer; and
through electrodes substantially passing through the peripheral region of the substrate body.

3. The semiconductor chip according to claim 2, wherein the semiconductor devices comprise, at least, any one of an image sensor, a memory semiconductor, a system semiconductor, a passive device, an active device, or a sensor semiconductor.

4. The semiconductor chip according to claim 2, further comprising:
a circuit pattern formed substantially on the one surface of the substrate body and the active layer,
wherein the circuit pattern comprises:
bonding pads formed substantially over a second surface of the circuit pattern generally facing away from a first surface of the circuit pattern which generally faces the one surface of the substrate body and the active layer, and the bonding pads being electrically connected with the through electrodes;
wiring layers electrically connecting the semiconductor devices to the through electrodes; and
a dielectric layer substantially isolating the semiconductor devices from the wiring layers, the wiring layers from one another, and the wiring layers from the bonding pads.

5. The semiconductor chip according to claim 4, wherein the through electrodes substantially pass through the circuit pattern and are directly connected to the bonding pads.

6. The semiconductor chip according to claim 4, wherein the through electrodes only pass through the peripheral region of the substrate body, the one surface, and the other surface.

7. The semiconductor chip according to claim 6, wherein the circuit pattern further includes additional wiring layers which electrically connect the through electrodes with the bonding pads.

8. A stacked semiconductor package comprising:
a plurality of semiconductor chips each including a semiconductor substrate including a substrate body divided into device regions and a peripheral region generally outside the device regions, and having one surface generally facing away from an other surface, and trenches which are defined generally in the device regions substantially on the one surface, and an active layer formed substantially in the trenches and made of polysilicon; semiconductor devices formed substantially over the active layer; and through electrodes passing through the peripheral region of the substrate body, the plurality of semiconductor chips being stacked such that their through electrodes are electrically connected with one another; and
conductive connection members electrically connecting the through electrodes of the stacked semiconductor chips.

9. The stacked semiconductor package according to claim 8, wherein the semiconductor devices of each semiconductor chip comprise, at least, any one of an image sensor, a memory semiconductor, a system semiconductor, a passive device, an active device, or a sensor semiconductor.

10. The stacked semiconductor package according to claim 8,
wherein each semiconductor chip further includes a circuit pattern formed substantially on the one surface of the substrate body and the active layer, and
wherein the circuit pattern comprises:
bonding pads formed substantially over a second surface of the circuit pattern generally facing away from a first surface of the circuit pattern which generally faces the one surface of the substrate body and the active layer, and the bonding pads being electrically connected with the through electrodes;
wiring layers electrically connecting the semiconductor devices to the through electrodes; and
a dielectric layer substantially isolating the semiconductor devices from the wiring layers, the wiring layers from one another, and the wiring layers from the bonding pads.

11. The stacked semiconductor package according to claim 10, wherein the through electrodes substantially pass through the circuit pattern and are directly connected to the bonding pads.

12. The stacked semiconductor package according to claim 10, wherein the through electrodes only pass through the peripheral region of the substrate body, the one surface, and the other surface.

13. The stacked semiconductor package according to claim 12, the circuit pattern further includes additional wiring layers which electrically connect the through electrodes with the bonding pads.

14. The stacked semiconductor package according to claim 8, further comprising:
a first dielectric layer formed, substantially under a lower surface of a lowermost semiconductor chip among the stacked semiconductor chips in, and formed to substantially expose the through electrodes of the lowermost semiconductor chip;
redistribution lines formed substantially under the first dielectric layer and electrically connected with the through electrodes substantially exposed through the first dielectric layer; and
a second dielectric layer formed, substantially under the first dielectric layer including the redistribution lines, and formed to expose portions of the redistribution lines.

15. The stacked semiconductor package according to claim 8, further comprising:
a structural body supporting the semiconductor chips and having connection electrodes which are electrically connected with the through electrodes of the lowermost semiconductor chip among the stacked semiconductor chips.

16. The stacked semiconductor package according to claim 15, wherein the structural body comprises any one of a printed circuit board, an interposer, or a semiconductor package.
